(19) United States
(12) Patent Application Publication
(10) Pub. No.: US 2023/0378405 A1
(43) Pub. Date: Nov. 23, 2023

(54) Systems With External Displays

(71) Applicant: Apple Inc., Cupertino, CA (US)

(72) Inventors: Yu P Sun, Yorba Linda, CA (US); Jun Qi, San Jose, CA (US); Rong Liu, Sunnyvale, CA (US); Ziruo Hong, San Jose, CA (US); Victor H Yin, Cupertino, CA (US); Tao Zhan, Saratoga, CA (US); Yong Seok Choi, Pleasanton, CA (US)

(21) Appl. No.: 18/182,118

(22) Filed: Mar. 10, 2023

Related U.S. Application Data
(60) Provisional application No. 63/343,038, filed on May 17, 2022.

(51) Int. Cl. H01L 33/58; H01L 25/075; B60Q 1/50

(52) U.S. Cl. CPC H01L 33/58; H01L 25/0753; B60Q 1/5035; G02B 5/0284

(57) ABSTRACT

A system may have an external display that presents content to viewers outside of the system. The external display may have a display panel with an array of pixels formed from light-emitting diodes. Optical films that help collimate and homogenize light from the light-emitting diode pixels may overlap the light-emitting diodes. A transparent cover may overlap the display. The transparent cover may have an outer surface and an opposing inner surface. The outer surface and inner surface may be planar or may have a curved cross-sectional profile. An optical louver layer or other solar rejection layer may be interposed between the inner surface of the transparent cover and the display panel. The louver layer may have a series of elongated parallel louvers formed from an opaque polymer or other material. The louvers may be configured to block sunlight reflections while allowing images on the display panel to be viewed.

This application claims the benefit of provisional patent application No. 63/343,038, filed May 17, 2022, which is hereby incorporated by reference herein in its entirety.

### FIELD

This relates generally to mobile systems, and, more particularly, systems that have external displays.

### BACKGROUND

Automobiles and other vehicles have propulsion and steering systems. Displays are used to present visual information.

### SUMMARY

A mobile system such as a vehicle may have displays. The displays may include external displays mounted on external surfaces of a mobile system body such as a vehicle body. Each display may have a display panel with an array of pixels. The pixels may be light-emitting diode pixels that each have a light-emitting diode such as a white light-emitting diode. During operation of the vehicle, the displays may display notifications and other information to pedestrians and others outside of the vehicle.

Each display may have one or more optical films that overlap the light-emitting diodes. The optical film(s) may include a microlens array and diffuser to help collimate and homogenize light from the light-emitting diodes.

A transparent cover may overlap the display. The transparent cover may have an outer surface and an opposing inner surface. The outer surface and inner surface may be planar or one or both of these surfaces may have a curved cross-sectional profile. A louver layer or other solar rejection layer may be interposed between the inner surface of the transparent cover and the display panel. The louver layer may have a series of elongated parallel louvers formed from opaque polymer or other opaque material. The louvers may run horizontally across the display. During operation of the display in sunny conditions, the louvers block sunlight reflections while allowing images on the display panel to be viewed. In this way, contrast may be enhanced for content displayed on the display in the presence of bright sunlight outside the vehicle.

### BRIEF DESCRIPTION OF THE DRAWINGS

FIG. 1 is a side view of an illustrative vehicle in accordance with an embodiment.

FIG. 2 is a side view of an illustrative display showing how the display may include a display panel, cover, and solar rejection filter located between the display panel and cover in accordance with an embodiment.

FIG. 3 is a side view of an illustrative display in accordance with an embodiment.

FIGS. 4, 5, and 6 are side views of illustrative displays having covers with different respective shapes in accordance with embodiments.

FIG. 7 is a side view of an illustrative asymmetric diffuser in accordance with an embodiment.

FIGS. 8 and 9 are illustrative louver layers that may serve as solar rejection filters in accordance with embodiments.

### DETAILED DESCRIPTION

A mobile system such as a vehicle or other system may have one or more externally mounted displays. A display mounted to the exterior of a system such as a vehicle will be exposed to sunlight. To help enhance image contrast on the display, the display may be provided with features that enhance performance in the presence of sunlight. For example, the display may include a solar rejection filter. The solar rejection filter may help suppress reflected sunlight, thereby improving the ability of a viewer of the display to discern text and/or other content that is presented on the display in sunny conditions.

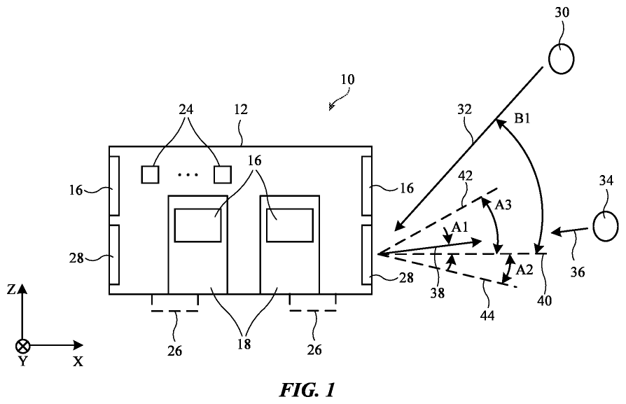

FIG. 1 is a side view of a portion of an illustrative vehicle. In the example of FIG. 1, vehicle 10 is the type of vehicle that may carry passengers (e.g., an automobile, truck, or other automotive vehicle). Configurations in which vehicle 10 is a robot (e.g., an autonomous robot) or other vehicle that does not carry human passengers may also be used. Vehicles such as automobiles may sometimes be described herein as an example.

Vehicle 10 may be manually driven (e.g., by a human driver), may be operated via remote control, and/or may be autonomously operated (e.g., by an autonomous driving system or other autonomous propulsion system). Vehicle 10 may include a body such as body 12. Body 12 may include vehicle structures such as body panels formed from metal and/or other materials, may include doors, a hood, a trunk, fenders, a chassis to which wheels 26 are mounted, a roof, etc. Windows 16 may be formed in doors 18 (e.g., on the sides of vehicle body 12), on the roof of vehicle 10, and/or in other portions of vehicle 10. Windows 16 and doors 18 and other portions of body 12 may separate the interior of vehicle 10 from the exterior environment that is surrounding vehicle 10.

Vehicle 10 may include one or more externally viewable displays 28. Each display 28 may be mounted to an external surface of body 12 so that images that are presented on the display are viewable by viewers in the external environment surrounding vehicle 10 such as viewer 34. Displays 28 may be mounted on the front, rear, left side, right side, and/or roof of vehicle 10, may be mounted at one, two, three, or four corners of vehicle 10 (e.g., at a front right corner, a front left corner, a rear right corner, and/or a rear left corner) or may be mounted at more central locations along the front side, left and right sides, and/or rear side of vehicle 10.

Vehicle 10 may include components 24. Components 24 may include propulsion and steering systems (e.g., manually adjustable driving systems and/or autonomous driving systems having wheels coupled to body 12, steering controls, one or more motors for driving the wheels, etc.), and other vehicle systems. Components 24 may include control circuitry and input-output devices. Control circuitry in components 24 may be configured to run an autonomous driving application, a navigation application, a vehicle status application, and other software for controlling vehicle 10. During operation, the control circuitry can use external displays 28 to provide notifications regarding the operation of vehicle 10 and other information to people in the vicinity of vehicle 10. For example, an external display may provide a viewer such as viewer 34 with text notifications such as “vehicle is stopped” or “vehicle is moving”. Icons (e.g., a stop sign icon), colored lights (e.g., a flashing light or steady light that is white or that has a non-white color such as red, yellow, green, or blue), and/or other visual output may also be provided using the visual output capabilities of external displays 28. In this way, displays 28 may be used to enhance pedestrian safety.

The control circuitry of vehicle 10 may include processing circuitry and storage and may be configured to perform operations in vehicle 10 using hardware (e.g., dedicated hardware or circuitry), firmware and/or software. Software code for performing operations in vehicle 10 and other data is stored on non-transitory computer readable storage media (e.g., tangible computer readable storage media) in the control circuitry. The software code may sometimes be referred to as software, data, program instructions, computer instructions, instructions, or code. The non-transitory computer readable storage media may include non-volatile memory such as non-volatile random-access memory, one or more hard drives (e.g., magnetic drives or solid state drives), one or more removable flash drives or other removable media, or other storage. Software stored on the non-transitory computer readable storage media may be executed on the processing circuitry of components 24. The processing circuitry may include application-specific integrated circuits with processing circuitry, one or more microprocessors, a central processing unit (CPU) or other processing circuitry.

The input-output devices of components 24 may include displays such as displays 28, sensors, buttons, light-emitting diodes and other light-emitting devices, haptic devices, speakers, and/or other devices for gathering environmental measurements, information on vehicle operations, and/or user input. The sensors in components 24 may include ambient light sensors, touch sensors, force sensors, proximity sensors, optical sensors such as cameras operating at visible, infrared, and/or ultraviolet wavelengths (e.g., fisheye cameras and/or other cameras), capacitive sensors, resistive sensors, ultrasonic sensors (e.g., ultrasonic distance sensors), microphones, three-dimensional and/or two-dimensional images sensors, radio-frequency sensors such as radar sensors, lidar (light detection and ranging) sensors, door open/close sensors, seat pressure sensors and other vehicle occupant sensors, window sensors, position sensors for monitoring location, orientation, and movement, speedometers, satellite positioning system sensors, and/or other sensors. Output devices in components 24 such as displays 28 may be used to provide people in the external environment surrounding vehicle 10 with output (e.g., visual output).

During operation, the control circuitry of components 24 may gather information from sensors and/or other input-output devices such as lidar data, camera data (images), radar data, and/or other sensor data. Cameras, touch sensors, physical controls, and other input devices may be used to gather user input. Using wireless communications with vehicle 10, remote data sources may provide the control circuitry of components 24 with database information (e.g., maps, still and/or moving images, audio, etc.). Media such as images and audio recordings may also be stored locally in storage in vehicle 10. Control circuitry in components 24 may use sensor data, user input, information supplied from remote databases, and other data when using displays 28 to present visual output to people in the external environment surrounding vehicle 10 and when providing other types of output.

There may be one, two, three, four, or more than four displays 28 in vehicle 10. The operation of a single display 28 may sometimes be described herein as an example.

As shown in FIG. 1, in an environment in which sunlight 32 (solar radiation) is emitted from sun 30, there is a possibility for unwanted solar glare on display 28. In the FIG. 1 example, display 28 is configured to emit light that travels in the +X direction towards viewer 34. This light may, as an example, be concentrated between lines 44 and 42 and may be characterized by primary emission direction 38 (which may be horizontal or nearly horizonal). In an illustrative embodiment, direction 38 may be oriented at a slight angle A1 above the X axis to facilitate viewing of content on display 28 by a pedestrian or other viewer who is looking slightly downward at display 28 in direction 36. Line 42 may be at an angle A3 above the +X axis and line 44 may be at an angle A2 below the +X axis. In an illustrative embodiment, A2 may be 15° and A3 may be 50°. Other angular light output boundaries (e.g., angles of +/−10-50% from these illustrative values) may be used, if desired.

To enhance visibility in bright sunlight, displays 28 may exploit the fact that bright sunlight 32 generally occurs at midday, when sun 30 is at an elevated position relative to the horizon (and is therefore oriented at an angle B1 relative to the +X axis that is greater than angle A1. In particular, displays 28 may have louvers or other structures that block display reflections associated with more highly angled light (such as sunlight 32) while passing horizontal (or nearly horizontal light emitted from display 28). The visibility of for content on display 28 is enhanced by blocking sunlight reflections and thereby enhancing contrast. The sunlight suppression structures that block sunlight reflections from display 28 are configured to decrease the amount of sunlight 32 that reflects back from display 28 along direction 38 to viewer 34 relative to the amount of display light that is emitted by display 28 along direction 38.

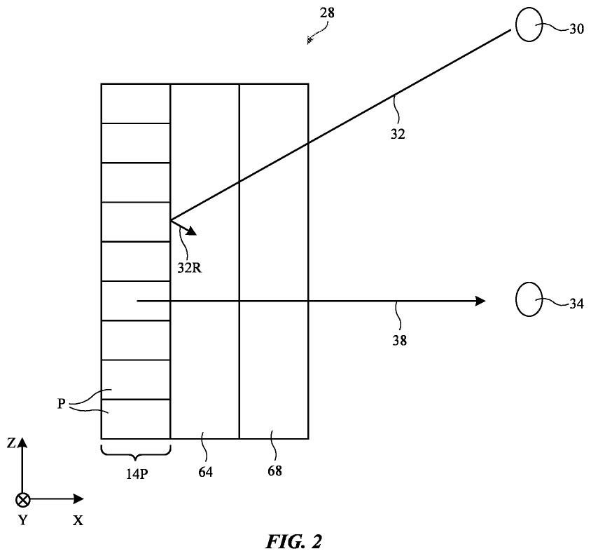

As shown in FIG. 2, display 28 may have a display panel 14P (sometimes referred to as a light plate assembly). Panel 14P may include an array of pixels P. Each pixel P may contain a respective light source such as a light-emitting diode. There may be any suitable number of pixels P in panel 14P (e.g., at least 100, at least 1000, at least 10,000, at least 1 million, etc.). Pixels P may have any suitable size. In an illustrative configuration, the lateral dimensions (when viewed from the exterior of vehicle 10) of pixels P may be on the order of fractions of a millimeter to multiple millimeters. The light-emitting diodes of panel 14P may be configured to emit white light and/or may be configured to emit non-white light (e.g., light of one or more colors, such as red, green, blue, yellow, orange, etc.). The use of white light, which may sometimes be described herein as an example, may help make content displayed by display 28 visible and may help avoid confusion with colored light from other light sources in vehicle 10. Display panel 14P may include light conditioning optics that overlap pixels P to help collimate and homogenize light emitted by pixels P.

Panel 14P may be overlapped by solar rejection filter layer 64. Layer 64, may include an array of louvers (e.g., a set of closely spaced parallel horizontal louvers that run horizontally across display 28) or other structures to help prevent reflection of sunlight 32 from display panel 14P. Layer 64 may sometimes be referred to as a louver layer, a sunlight rejection filter, a sunlight reflection blocking filter, a sunlight suppression filter, or an angle-of-incidence-based light reflection suppression layer. Layer 64 may help absorb and thereby block reflected sunlight 32R.

Layer 64 may be covered by a protective structure such as cover 68. Cover 68 may be formed from clear or tinted polymer, clear or tinted glass, and/or other transparent material(s) to allow light 38 that is emitted by display panel 14P to be viewed by viewer 34.

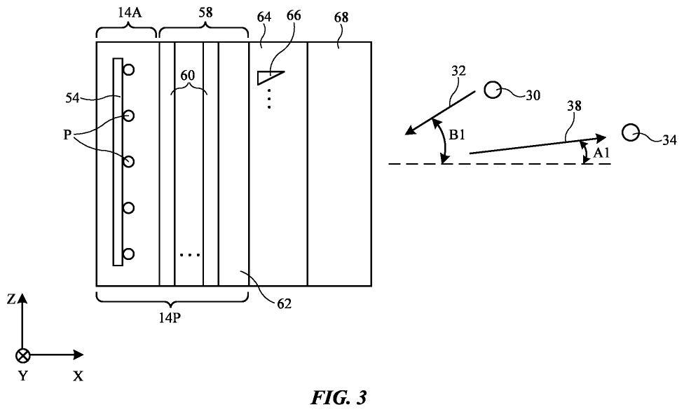

FIG. 3 is a cross-sectional side view of display 28 showing illustrative layers that may be included in display panel 14P. As shown in FIG. 3, display panel 14P may include an array of pixels P such as pixel array 14A. Pixels P may be formed from light-emitting diodes (e.g., white light-emitting diodes or other light-emitting diodes) that are mounted in an array on a substrate such as printed circuit substrate 54. Display panel 14P may also include light conditioning optics 58. Light conditioning optics 58 may include, for example, collimating optics such as reflectors and lenses as well as a stack of optical conditioning films that overlap pixels P. These films may include, for example, one or more optical films 60. Films 60 may include an array of microlenses to help collimate emitted light from the light-emitting diodes of pixels P and may include other optical structures to help condition the emitted light. The stack of optical conditioning films in optics 58 may include an optional diffuser such as diffuser 62. Diffuser 62 may be, for example, an asymmetric diffuser that reflects sunlight asymmetrically (e.g., so that this reflected light exhibits enhanced absorption within louvre layer 64). This may help to suppress solar reflections due to sunlight 32 from sun 30 that could obscure the viewing of display light from panel 14P that is emitted in direction 38 for viewing by viewer 34.

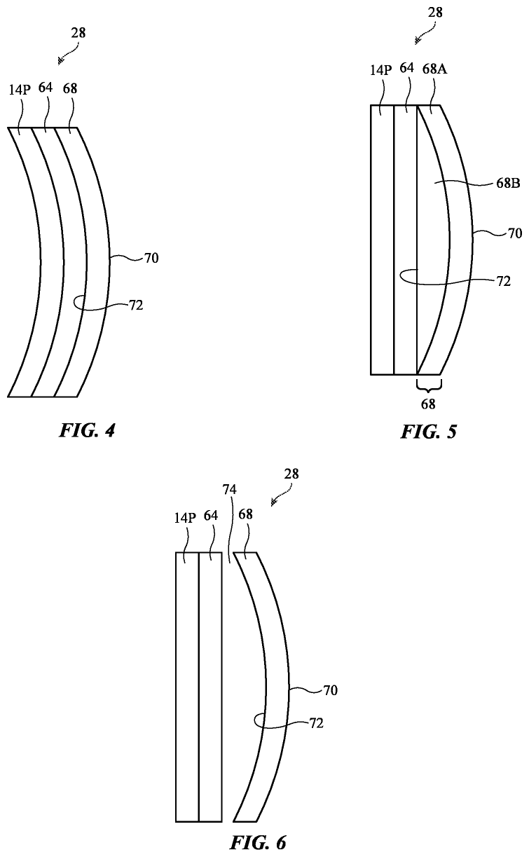

In the example of FIG. 3, display layer 14P, louver layer 64, and cover 68 are laminated together (e.g., using interposed layers of optically clear adhesive to attach these structures directly to each other). Cover 68 of FIG. 3 also has inner and outer surfaces that are planar. Other arrangements may be used for display 28, if desired. As shown in FIGS. 4, 5, and 6, for example, display 28 may have a cover with at least one curved surface. In the FIG. 4 example, inner surface 72 and outer surface 70 of cover 68 are curved (e.g., these surface have curved cross-sectional profiles) and outer surface 70 is convex. In this type of configuration, panel 14P and louver layer 64 may have curved shapes that match the curved shape of surface 70 (e.g., so that panel 14P, layer 64, and cover 68 may be laminated directly together). In the FIG. 5 example, inner surface 72 of cover 68 is planar. Cover 68 may be formed, for example, from a first portion 68A (e.g., a first shot of polymer or a glass member) having curved inner and outer surfaces and a second portion 68B (e.g., a second shot of polymer) that has a curved outer surface that matches the curved inner surface of portion 68A and a corresponding planar inner surface (surface 72). In this arrangement, panel 14P and louver layer 64 may be planar layers. In the example of FIG. 6, cover 68 is separated from louver layer 64 by air gap 74. This allows inner surface 72 and outer surface 70 to be curved while using planar structures to form panel 14P and louver layer 64.

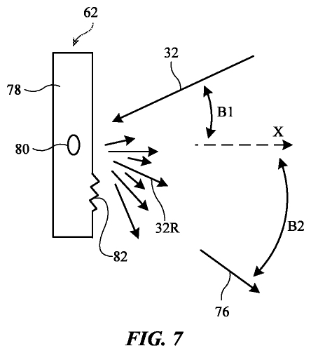

FIG. 7 is a cross-sectional side view of an illustrative diffuser for panel 14P. As shown in FIG. 7, diffuser 62 may be formed from a layer of polymer 78 or other transparent material with embedded light-scattering particles 80. Particles 80 may be, for example, inorganic particles (e.g., titanium dioxide particles or other particles) having an index of refraction that differs from that of polymer 78. Particles 80 may have any suitable shape. With an illustrative configuration, particles 80 may have a shape (e.g., an elliptical cross section) that promotes asymmetric diffusion of reflected light 32R. Surface texture 82 may also be formed by embossing or other techniques to enhance the asymmetric diffusion properties of diffuser 62. Surface texture 82 may be formed on either side of diffuser 62 (e.g., facing the sun and/or facing panel 14P). Due to asymmetric diffusion properties of diffuser 62, incoming sunlight 32 that is angled at angle B1 with respect to the X axis (which is parallel to the surface normal of layer 62) will produce reflected light 32R whose principal direction of propagation 76 is angled at a larger angle B2 with respect to the X axis (e.g., B2 will be larger than B1). This may help enhance the ability of louver layer 64 to block reflected light 32R, because light traveling along direction 76 will tend to be blocked more by the louvers of layer 64 than light traveling at an angle that is oriented more parallel to the X axis.

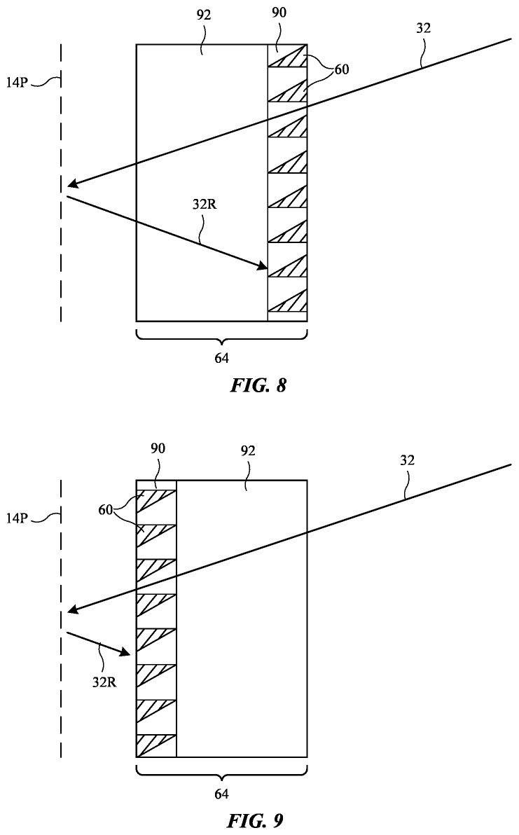

FIGS. 8 and 9 are cross-sectional side views of illustrative louver layers 64 for display 28. As shown in FIGS. 8 and 9, louvers 60 may be configured to preferentially allow steeply angled incoming sunlight 32 to pass through the gaps between adjacent louvers and pass through layer 64, while blocking corresponding light 32R that is reflected downwardly and outwardly from panel 14P. In the example of FIGS. 8 and 9, this light-blocking property is achieved using opaque louvers 60 with triangular cross-sectional shapes, but other shapes of louvers 60 may be used, provided that the louvers 60 are oriented so that incoming sunlight 32 (e.g., sunlight that is incoming into display 28 from the exterior of vehicle 10 at an elevated angle as expected when the sun is high in the sky) is allowed to pass while corresponding light 32R that is produced when the incoming sunlight reflects from panel 14P (e.g., from pixel array 14A and from optics 58) is blocked (e.g., by being absorbed by the opaque material making up louvers 60). Louvers 60 may exhibit cross-sectional dimensions that are generally much less than the lateral dimensions of pixels P. For example, whereas pixels P may have mm-sized dimensions, louvers 60 may have cross-sectional dimensions on the orders of tens of microns. The gaps between adjacent louvers 60 may have this order of magnitude. As a result, louvers 60 may be about 10 or 100 times smaller than pixels P. Other dimensions for pixels P and louvers 60 may be used, if desired.

In the example of FIG. 8, louvers 60 are formed within an outward-facing coating of polymer 90 supported on the outer (exterior-facing) surface of polymer film 92 (e.g., a polymer substrate formed from a material such as polyethylene terephthalate). In the example of FIG. 9, louvers 60 are formed in coating 90 on the inner surface of polymer film 92. If desired, louvers 60 may be formed directly from lines of opaque material on the inner surface of cover 68 (e.g., in parallel horizontal grooves formed in cover 68).

To help maximize light absorption of reflected light 32R, light reflections at the interface between polymer 90 and the polymer forming louvers 60 may be minimized. These light reflections from louvers 60 may be minimized, for example, by forming louvers 60 and polymer 90 from index-matched materials (e.g., first and second respective materials with first and second respective refractive indices with magnitudes that differ by less than 2%, less than 1%, less than 0.5%, less than 0.2%, or other suitable amount). These light reflections may also be minimized by texturing the surfaces of louvers 60. Louvers 60 that are index matched to polymer 90 and that have textured surfaces will generally not reflect light 32R, so more of light 32R will be absorbed by louvers 60 and will therefore be prevented from exiting display 28 and being viewed by viewer 34.

During exposure to sunlight, louver layer 64 tends to absorb solar energy. Excessive solar loading on the materials forming louver layer 64 may degrade louver layer 64. To enhance reliability, it may be desirable to reduce solar loading on layer 64. This may be accomplished by including a dichroic coating on the outwardly facing surface of louver layer 64 (e.g., at the interface between layer 64 and cover 68) and/or by including a dichroic coating on the inner surface of cover 68 (at the interface between layer 64 and cover 68) and/or the outer surface of cover 68. The dichroic coating may be configured to reflect incoming solar radiation (e.g., ultraviolet and/or infrared light from the sun) and thereby reduce solar aging effects on layer 64. The dichroic coating may have a pass band that is configured to allow emitted display light from the array of pixels to pass without significant attenuation. For example, the dichroic coating may have a transmission of at least 80%, at least 90%, or at least 97% for emitted display light (which may be, for example, visible light such as white display light or display light of one or more colors). The dichroic coating may include a stack of thin-film layers (e.g., dielectric layers such as silicon oxide, silicon nitride, metal oxides, etc.) having alternating higher and lower refractive index values. The thicknesses and refractive index values of the thin-film layers of the dichroic coating may be configured to reflect infrared and/or ultraviolet solar radiation (e.g., the coating may exhibit a reflectivity of at least 50%, at least 70%, or at least 90% for ultraviolet light, infrared light and/or other non-display-light wavelengths that are different than the visible light wavelengths of the emitted display light), while exhibiting a satisfactorily high transmission (e.g., at least 80%, at least 90%, at least 97%, etc.) for emitted display light (e.g., visible light). By reflecting more infrared (and/or, if desired, ultraviolet light) than visible light with a dichroic coating that lies between the exterior environment surrounding of the vehicle body and sensitive components such as louver layer 64, displays 28 may operate satisfactorily while solar radiation is prevented from damaging sensitive components behind the dichroic coating such as louver layer 64.

The foregoing is merely illustrative and various modifications can be made to the described embodiments. The foregoing embodiments may be implemented individually or in any combination.

What is claimed is:

1. A mobile system, comprising:
a mobile system body having an exterior and interior; and
a display on the exterior, wherein the display comprises:
an array of pixels configured to emit display light;
a cover; and
a louver layer between the array of pixels and the cover, wherein the louver layer and the cover are configured to pass the emitted display light.

2. The mobile system defined in claim 1 wherein the array of pixels comprises an array of light-emitting diodes.

3. The mobile system defined in claim 2 wherein the light-emitting diodes of the array of pixels are white light-emitting diodes.

4. The mobile system defined in claim 1 wherein the louver layer comprises a plurality of elongated louvers running horizontally across the display.

5. The mobile system defined in claim 1 wherein the louver layer comprises a plurality of parallel louvers each having a triangular cross-sectional shape.

6. The mobile system defined in claim 1 wherein the louver layer is configured to pass incoming sunlight to the array of pixels while blocking portions of the incoming sunlight that have reflected outwardly off of the array of pixels.

7. The mobile system defined in claim 1 further comprising a diffuser between the array of pixels and the louver layer.

8. The mobile system defined in claim 7 wherein the diffuser comprises an asymmetric diffuser layer that is configured to reflect incoming sunlight rays at an angle that enhances absorption by the louver layer.

9. The mobile system defined in claim 1 wherein the louver layer comprises a polymer in which opaque louvers are embedded.

10. The mobile system defined in claim 9 wherein the polymer and the opaque louvers have refractive index values that differ by less than 0.5%.

11. The mobile system defined in claim 9 wherein the opaque louvers have textured surfaces to enhance absorption of light reflected from the array of pixels.

12. The mobile system defined in claim 1 further comprising optical conditioning structures configured to homogenize the display light emitted from the pixels.

13. The mobile system defined in claim 1 further comprising an air gap between the louver layer and the cover.

14. The mobile system defined in claim 13 wherein the cover has an outer surface with a curved cross-sectional profile.

15. The mobile system defined in claim 14 wherein the cover has an opposing inner surface with a curved cross-sectional profile and wherein the louver layer has a curved louver layer surface that is attached to the inner surface.

16. The mobile system defined in claim 15 wherein the cover has an opposing inner surface with a curved cross-sectional profile and wherein the louver layer and the inner surface are separated by an air gap.

17. The mobile system defined in claim 15 wherein the cover has an opposing planar inner surface and wherein the louver layer has a planar surface that is attached to the planar inner surface.

18. The mobile system defined in claim 1 further comprising a dichroic coating between the louver layer and an exterior environment surrounding the mobile system body.

19. The mobile system defined in claim 18 wherein the dichroic coating is configured to reflect more infrared light than visible light.

20. The mobile system defined in claim 18 wherein the dichroic coating is configured to reflect more ultraviolet light than visible light.

21. The mobile system defined in claim 1 further comprising a dichroic coating on an outwardly facing surface of the louver layer that is configured to pass the emitted display light while reflecting infrared and ultraviolet solar radiation.

22. A vehicle comprising:
a vehicle body;
a display panel supported by the vehicle body that has an array of light-emitting diodes configured to emit display light outwardly from the vehicle body; and
a louver layer that covers the display panel, wherein the louver layer is configured to pass the emitted display light while blocking sunlight reflections from the display layer to enhance visibility of content on the display panel.

23. The vehicle defined in claim 22 wherein the louver layer has a plurality of horizontal parallel elongated louvers with triangular cross sections.

24. An external vehicle display, comprising:
a display panel having an array of light-emitting diode pixels, an optical film configured to homogenize light emitted from the light-emitting diode pixels;
a transparent cover; and
a louver layer between the transparent cover and the display panel, wherein the louver layer is configured to pass the homogenized light.

25. The external display defined in claim 24 wherein the louver layer comprises opaque louvers embedded in polymer.
